(19) United States
(12) Patent Application Publication
(10) Pub. No.: US 2023/0357025 A1
(43) Pub. Date: Nov. 9, 2023

(54) PROCESS FOR ISOTHERMAL DIAMOND ANNEALING FOR STRESS RELAXATION AND OPTICAL ENHANCEMENT BY RADIATIVE HEATING

(71) Applicant: M7D Corporation, Beltsville, MD (US)

(72) Inventors: John Ciraldo, Clarksburg, MD (US); Jonathan Levine-Miles, Beltsville, MD (US); Joshua Blackketter, Laurel, MD (US); Jean-Claude Remy, Beltsville, MD (US)

(21) Appl. No.: 17/739,918

(22) Filed: May 9, 2022

(51) Int. Cl. C01B 32/28

(52) U.S. Cl. CPC C01B 32/28

(57) ABSTRACT

A method anneals one or more diamonds. The method provides a furnace having a chamber with a heating element configured to radiatively heat a diamond. The diamond is positioned within the chamber, and levels of gas within the chamber are modulated to achieve a prescribed pressure. The diamond is heated to a prescribed temperature using a given heating ramp rate. The given heating ramp rate is greater than about 60° C. per minute and less than about 800° C. per minute. The prescribed temperature is greater than about 1,350° C. and less than about 2,200° C. The prescribed pressure is greater than 1×10\hat{ }−9 Torr and less than about 550 Torr.

### FIELD OF THE INVENTION

Illustrative embodiments of the invention generally relate to growing diamonds and, more particularly, the various embodiments of the invention relate to processes for improving optical and stress properties of diamonds.

### BACKGROUND OF THE INVENTION

Diamonds are used in a wide variety of applications in addition to their use as gemstones. For example, diamonds can be used for producing integrated circuits, or as lenses for laser systems. Growing diamonds, however, can present a number of technical challenges. Additionally, as diamond are grown, they may contain impurities that cause undesirable colors in the diamond.

Single crystal diamonds often contain synthesis impurities due to the manufacturing process which can be removed or mitigated using a thermal process during the diamond growth process, improving color. Previous methods use smaller batches with long cycle times, which limits the number of stones that can be used in a given amount of time, or extremely high pressures, with accompanying equipment expense. Several parameters provide failure states outside of which the crystals are no longer viable for gem sales, constraining the options available for the thermal process.

### SUMMARY OF VARIOUS EMBODIMENTS

In accordance with one embodiment, a method anneals one or more diamonds. The method provides a furnace having a chamber with a heating element configured to radiatively heat a diamond. The diamond is positioned within the chamber, and levels of gas within the chamber are modulated to achieve a prescribed pressure. The diamond is heated to a prescribed temperature using a given heating ramp rate. The given heating ramp rate is greater than about 60° C. per minute and less than about 800° C. per minute. The prescribed temperature is greater than about 1,350° C. and less than about 2,200° C. The prescribed pressure is greater than 1×10\hat{ }−9 Torr and less than about 550 Torr.

In various embodiments, the ramp rate may accelerate as it approaches the prescribed temperature. Alternatively, the ramp rate may deaccelerate as it approaches the prescribed temperature. In some embodiments, the prescribed temperature is a maximum temperature. Preferably, the prescribed temperature and/or the maximum temperature is sustained for a time that is more than an order of magnitude less than a ramp time. For example, the prescribed temperature and/or the maximum temperature may be sustained for less than 30 seconds, less than 2 seconds, or less than 1 second.

In some embodiments, the ramp rate is between about 150° C. per minute and about 500° C. per minute. The prescribed temperature may be between about 1,750° C. and about 2,100° C. The heating element may be a radiative heating element. Accordingly, various embodiments prevent or reduce graphitization of the diamond. The method may also position a plurality of diamonds within the chamber. Thus, the plurality of diamonds may simultaneously be heated at the given ramp rate to achieve substantial thermal uniformity for each of the diamonds at the prescribed temperature. Various embodiments may accommodate a number of diamonds that are heated with substantial uniformity, such as 50 diamonds or more. The plurality of diamonds may be maintained at substantially the same temperature within a hot zone produced by the radiative heating elements.

Among other things, the prescribed gas environment may include hydrogen. Additionally, or alternatively, the prescribed gas environment may include argon and/or nitrogen. Various embodiments reduce the oxygen in the gas environment to less than 1 ppm. The partial pressure of oxygen in the chamber may be less than 10 milliTorr.

In accordance with another embodiment, a method anneals a plurality of diamonds. The method provides a furnace having a chamber with a heating element configured to radiatively heat the plurality of diamonds. The plurality of diamonds are positioned within the chamber, and levels of gas within the chamber are modulated to achieve a prescribed pressure. The radiative heating elements produce a hot zone within the chamber. The hot zone defines a volume that encompasses the one or more diamonds and has substantial thermal uniformity throughout the volume. The hot zone may be considered to be substantially thermally uniform when the temperature variance within the hot zone is 25° C. or less at any given time (e.g., at the peak temperature). In various embodiments, the volume is configured to encompass the plurality of diamonds. The plurality of diamonds are heated within the hot zone to a prescribed temperature using a given heating ramp rate. The given heating ramp rate is greater than about 60° C. per minute and less than about 800° C. per minute. The prescribed temperature is greater than about 1,350° C. and less than about 2,200° C. The prescribed pressure is greater than 1×10\hat{ }−9 Torr and less than about 550 Torr. In some embodiments, the thermal uniformity through the hot zone may be+−5% of a maximum temperature in the hot zone.

In some embodiments, the thermal variance in the hot zone may be less than 5%, less than 3%, or less than 1% of a maximum temperature of the hot zone. The thermal variance in the hot zone may be less than 100° C., less than 70° C., less than 50° C., or less than 25° C.

The diamonds may be heated within the hot zone. The hot zone may form a cylindrical volume, among other things. The hot zone may have a width or diameter of between about 3 inches and about 5 inches. The hot zone may also have a height of between about 3 inches and about 7 inches. In various embodiments, the processes described herein result in less than 1% loss of diamond by weight due to graphitization. In some embodiments, the hot zone may define a volume with boundaries that are substantially defined by the outer surface of the one or more diamonds.

In accordance with yet another embodiment, a method reduces undesirable coloration in a diamond. The method provides a diamond having a discoloration. The diamond is annealed in a furnace having a chamber at a pressure of between about 40 Torr and about 550 Torr. The diamond is radiatively heated to a maximum temperature of between about 1,350° C. and about 2,200° C., so as to reduce the discoloration.

The method may position the diamond having the discoloration in an annealing chamber. The annealing chamber may also be a diamond growth chamber. In various embodiments, the heating ramp rate may be between about 150° C. and about 800° C. The annealing may take place in the presence of hydrogen and/or an inert gas, such as argon.

In accordance with yet another embodiment, a furnace heats the diamonds. The furnace includes a hermetically sealed chamber. The furnace has a growth stage in the hermetically sealed chamber. The growth stage is configured to hold a plurality of diamonds. A radiative heating element is configured to heat the plurality diamonds to prescribed temperatures of between about 1,350° C. and less than about 2,200° C. The radiative heating element is further configured increase temperatures within the chamber at a ramp rate of between about 60° C. per minute and about 800° C. per minute when heating at and/or to the prescribed temperature range.

In various embodiments, the furnace may include a pressure modulation system configured to adjust a pressure within the chamber. The pressure modulation system may be configured to adjust the pressure within the chamber from between about 1×10\hat{ }−9 Torr and less than about 550 Torr. To that end, the pressure modulation system may comprise a gas input and a gas output.

In accordance with one embodiment of the invention, a method uses radiative heating in a low pressure (less than 0.5 atm), high temperature (>1400C) environment to isothermally anneal diamonds in a substantially uniform temperature hot zone. The thermal process provides desired optical improvement and stress relaxation while minimizing cracking, etching, graphitization, and other failure modes to single-crystal diamond.

In various embodiments, the isothermal environment is within a furnace designed to maintain temperature uniformity throughout a hot zone where the diamond material is positioned. In particular, the isothermal environment may be considered isothermal when the temperature in the hot zone has a variance of less than 3% of a maximum temperature in the hot zone, described herein as having a 3% uniformity.

Among other types of diamond that are annealed, the diamond may be grown using a chemical vapor deposition process. Furthermore, other materials may also be annealed (e.g., sapphire).

Illustrative embodiments of the invention are implemented as a computer program product having a computer usable medium with computer readable program code thereon. The computer readable code may be read and utilized by a computer system in accordance with conventional processes.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a process of annealing diamonds in accordance with illustrative embodiments of the invention.

FIG. 2 schematically shows a furnace 10 in accordance with illustrative embodiments of the invention.

FIGS. 3 and 4A schematically show exemplary heating ramp rates in accordance with illustrative embodiments of the invention.

FIG. 4B schematically shows a close-up of a portion of FIG. 4A.

FIG. 4C schematically shows an alternative configuration of ramp rate shown in FIG. 4B.

It should be noted that the foregoing figures and the elements depicted therein are not necessarily drawn to consistent scale or to any scale. Unless the context otherwise suggests, like elements are indicated by like numerals. The drawings are primarily for illustrative purposes and are not intended to limit the scope of the inventive subject matter described herein.

### DESCRIPTION OF ILLUSTRATIVE EMBODIMENTS

Illustrative embodiments use a furnace to provide a production-scale process for annealing diamonds. This is in contrast to plasma mediated low-pressure high-temperature (LPHT) annealing (e.g., plasma mediated) or medium-pressure high-temperature (MPHT) annealing. LPHT and MPHT processes generally work for a small number of diamonds at a time. While these processes work well, they are not production-scale, and they are a bit imprecise and lack repeatability (because of the challenge of controlling temperature). Furthermore, these processes require specific pressures that require pumping of air pressure within the chamber repeatedly. Illustrative embodiments thermally process diamonds (or other gemstones) under low pressure (LP). The LP furnace process has substantially no thermal gradient over a plurality of stones, provides better control over the temperature of the stones, enables larger batch size capability, and is simpler to maintain.

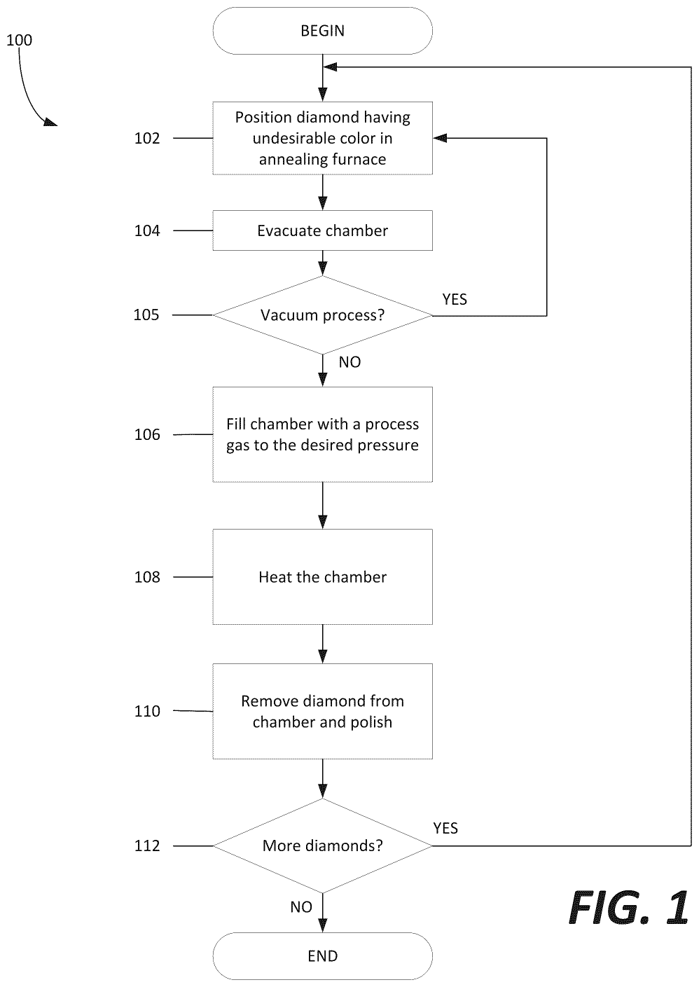

FIG. 1 schematically shows a process 100 of annealing diamonds in accordance with illustrative embodiments of the invention. While the process is discussed with reference to diamond, it should be understood that the process may be used with a variety of other materials.

It should be noted that this process 100 is simplified from a longer process that normally would be used to anneal diamonds. Accordingly, the process of annealing diamonds likely has many steps that those skilled in the art likely would use. In addition, some of the steps may be performed in a different order than that shown. Additionally, or alternatively, some of the steps may be performed at the same time or skipped altogether. Those skilled in the art therefore can modify the process as appropriate.

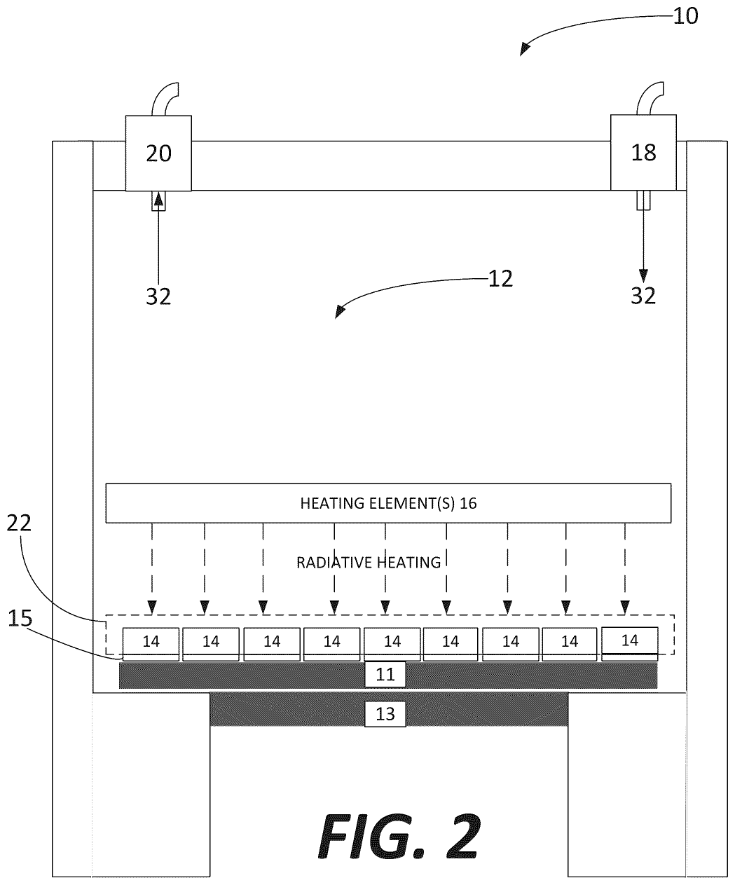

The process begins at step 102, which positions diamond in an annealing furnace. FIG. 2 schematically shows a furnace 10 in accordance with illustrative embodiments of the invention. Illustrative embodiments provide an isothermic furnace 10, and produce a growth/heating environment in the furnace 10 that hinders or reduces formation of sp² bonds (i.e., by preventing exposure to oxygen). The formation on sp² bonds undesirably causes “graphitization” of the carbon, rendering its value substantially lower and/or useless for particular applications. As described herein, the conditions of a LPHT or MPHT process may be provided without the need for a plasma (i.e., illustrative embodiments enable a plasma-free process). LPHT/MPHT processes use a plasma chamber. In general, plasma heats diamonds 14 non-uniformly (i.e., depending on their position within the chamber 12), and therefore, the stones 14 do not reach substantially the same temperature.

In contrast, illustrative embodiments provide substantially uniform temperature gradient (also referred to as a hot zone 22) across one or more stones 14 using the radiative furnace 10. In some embodiments, one or more stones are within the hot zone. However, preferred embodiments preferably include a plurality of stones 10 within the hot zone 22 having a temperature uniformity (e.g., a thermal variance of less than about 100° C.).

The thermal process described in various embodiments may achieve the same optical quality as plasma LPHT or plasma MPHT annealing processes, but without the use of plasma. Various embodiments advantageously radiatively heat the stones 14, and therefore, are able to more uniformly heat a hot zone 22 than plasma-mediated processes (i.e., enable scalability by simultaneously processing more stones than comparable plasma processes). Thus, illustrative embodiments provide a plurality of diamonds 14 that may be thermally processed simultaneously.

Throughout the application, the term “uniform” may be used to refer to heating of the hot zone 22 and/or the diamonds 14 within the hot zone 22. At the temperatures described herein (e.g., 2,000 degrees C.), accurately measuring temperature can become difficult. For this reason, heating may be considered to be “uniform” when the measured temperature of the one or more diamonds in the “uniform” hot zone is within 16 degrees C. of a target temperature (e.g., an oven setting temperature, or a maximum temperature in the oven). In some embodiments, the hot zone may be a discontinuous volume. For example, the hot zone may be defined by the space/volume that is occupied by the one or more diamonds.

In some embodiments, the furnace 10 may be used to grow the diamonds 14 (e.g., using CVD), and the diamonds 14 may be thermally processed after growth. However, in some embodiments, the diamonds 14 may be thermally processed during growth. As known by those of skill in the art, the diamond 14 may be grown on a diamond seed 15 within a chamber 12 of the furnace 10 (e.g., inside the vacuum sealed CVD chamber 12 as shown in FIG. 2). Specifically, the diamond seed(s) 15 may be positioned on a refractory metal support 11, which itself may be on a temperature-controlled growth stage 13. Although illustrative embodiments refer to diamond 14 growth, among other things, the seed 15 may be formed on, for example, magnesium oxide, iridium, silicon, yttrium-stabilized zirconium, titanium, silicon carbide, diamond, or combinations thereof. Those skilled in the art may select yet a different material for the seed 15. Preferably, the seed 15 has a single crystal/monocrystalline structure. In illustrative embodiments where the seed 15 is formed from diamond, the seed 15 growth surface may have, among other things, a (100) crystal orientation with a miscut/misorientation in the range of about ±5 degrees.

In various embodiments, one or more diamonds 14 may be positioned within the chamber 12. Furthermore, although the diamonds 14 are shown as being aligned on a planar surface, in some embodiments, the diamonds 14 may be positioned in other configurations (e.g., to maintain a desired heat gradient relative to a heating element 16). Various embodiments heat a plurality of diamonds 14 within a substantially uniform hot zone 22 (e.g., the hot zone 22 may be curved to match positioning of diamonds 14 on a sloped surface).

In some other embodiments, however, the diamonds 14 may not be grown in the furnace 10. Thus, the diamonds 14 may be naturally formed or grown outside the furnace 10, and then subsequently positioned in the chamber 12. However, for purposes of this discussion, growing the diamond 14 within the furnace is also considered to be positioning the diamond with the furnace 10.

The furnace 10 may have a gas input 18 configured to bring gas 32 into the chamber 12. Additionally, the furnace 10 may have a gas output 20 configured to output gas 32 from the chamber 12. It should be understood that the shape, arrangement, and position of the walls, heating elements, gas input and output, are merely illustrative, and not intended to limit various embodiments.

The furnace 10 includes one or more heating elements 16 configured to heat the diamond 14. It should be noted that various embodiments refer to the heating element 16, but are intended to include one or more heating elements 16 that achieve the same functionality described herein. The heating element 16 is configured to provide a uniform thermal gradient (i.e., hot zone 22) across the various diamonds 14 positioned in the chamber 12. The uniform thermal gradient (e.g., having a temperature variance of less than about 100 degrees throughout the hot zone, a variance of less than about 25 degrees throughout the hot zone, or a variance of less than about 16 degrees) provides a number of advantages. For example, if the diamond 14 is too hot, it may explode, shatter, or become an undesirable color (e.g., gray).

Indeed, it was thought in the art that the temperatures used in various embodiments described herein would result in graphitization of the diamond 14. For example, see Eaton-Magana et al. (LPHT annealing of brown-to-yellow type Ia diamonds. Diam. Relat. Mater., 77 (2017), pp. 159-170). Eaton-Magana, in section 3.1, describes an average weight loss of 15% due to graphitization. In contrast, illustrative embodiments provide substantial color improvement without high amounts of diamond loss due to graphitization. Various embodiments provide satisfactory annealing with less than 2% weight loss due to graphitization. Preferably, various embodiments provide less than 1% weight loss due to graphitization. While difficult to pinpoint, illustrative embodiments theoretically lose some weight to graphitization, but that weight is so low in some embodiments, that it is not reliably measurable using scales that can weigh 1/100 of gram. Therefore, it is hypothesized that some graphitization occurs on the order of less than 1/100^{th} of a gram (e.g., 1 picogram or less), but it is not practicably measurable using current tools available to the inventors.

Alternatively, if the temperature is too cold, the diamond 14 may not anneal properly. Therefore, various embodiments provide a finely controlled range of temperatures in which the diamond 14 is heated (e.g., the hot zone 22 is within +−16 degrees C.). In preferred embodiments, the furnace 10 has one or more of the following qualities:
a fast heating ramp rate (i.e., the rate at which the temperature within the chamber 12 increases, and/or the rate at which the temperature within the chamber 12 decreases),
an external radiative element 16 (i.e., not in direct contact with the diamond 14, in contrast to electrified crucible, where the crucible becomes the heating element.)
a hermetically sealed chamber 12,
an ability to pump down to vacuum or near vacuum, e.g., below 1.0×10⁻² Torr (also referred to as below 10 milliTorr),
a chamber 12 having a relatively large uniformly heated hot zone 22 for a reasonably large number of stones (e.g., 4″ diameter×7″ height cylinder hot zone 22, encompassing about 100 stones or more), and/or
an accurate temperature control.

The process then proceeds to step 104, where the annealing chamber 12 is evacuated. Accordingly, any unintended gas 32 in the chamber 12 may be removed from the chamber 12 prior to pressurizing or heating the diamond 14. In various embodiments, the chamber 12 inside the furnace 10 is pumped down to 10 milliTorr to remove air from the chamber.

Returning to FIG. 1, the process then proceeds to step 105, which asks whether the process 100 will be performed at vacuum. If yes, then the process returns to step 102, which positions the diamonds 14 within the chamber 12. Specifically, in various embodiments performing the annealing under vacuum, the diamonds 14 may be positioned (or repositioned) a uniform distance from the heating element 16 (e.g., because gas 32 is not present to assist with thermal transport). Although the process 105 is described as occurring after steps 102 and 104, this is merely for the sake of discussion. It should be understood that in various embodiments, it is known ahead of time whether the process 100 will be performed at vacuum, and therefore adjustments may be made to the position of the diamonds 14 at the original onset of step 102.

If the process is not performed at vacuum (e.g., low pressure), the process proceeds to step 106, which fills the annealing chamber 12 with a process gas 32 until the chamber 12 reaches the desired pressure. Accordingly, it should be understood that various embodiments may provide a vacuum process or a pressurized process. The pressurized process may allow for processing more diamonds 14 (e.g., because the process gas 32 helps transport heat more uniformly), but may add complexity to the overall process. In various embodiments, the pressure within the chamber 12 may reach between 1×10\hat{ }−5 Torr (e.g., high-vac) and 550 Torr. In various embodiments, the pump is capable of much lower pressures (e.g., 1×10\hat{ }−9 Torr because of outgassing; 1 nanoTorr). Various embodiments may include a diffusion pump that reduces the pressure within the chamber 12 to as low as about 1×10\hat{ }−7 Torr. Preferably, various embodiments pressurize the chamber 12 to below about 200 Torr.

Illustrative embodiments may provide different types of gas environments, depending on an intended outcome. Various embodiments provide two different types of gas environments:
(1) Inert environment (e.g., using argon and/or any other noble gas), and/or
(2) Reducing environment (e.g., using hydrogen).

The reducing environment advantageously reduces graphitization of sp² bonded carbon. As the furnace 10 is heated, the furnace 10 tends to outgas. Thus, oxygen comes out of the furnace 10 during the process. Oxygen may flow from the metal heating elements 16 (and whatever else may be in the furnace 10) into the chamber 12 environment as the heating elements 16 are heated. The oxygen may undesirably react with the diamond 14 and cause graphitization and/or destruction of the diamond 14 material. In the reducing environment, the hydrogen reacts with the oxygen to produce water, thereby reducing undesirable effects of oxygen. In the inert environment, the chamber 12 is saturated with another gas such that it suppresses the impact of the oxygen. The vacuum process constantly pumps out the oxygen. Accordingly, various embodiments may use different methods of reducing/removing oxygen in the chamber 12, thereby reducing graphitization of the diamond 14.

As described above, in illustrative embodiments, the pressure in the chamber 12 reaches between about 40 Torr and 550 Torr. For example, in some embodiments, the chamber pressure may be greater than 150 Torr. In some embodiments, the pressure in the chamber may reach 400 Torr.

The inventors discovered that pressurizing the gas in the chamber 12 to the above described ranges provides advantageous conditions. For example, the higher pressured gas offers improved thermal conduction, thereby reducing thermal inhomogeneity. The improvement in thermal uniformity results in lower stress in the annealed diamonds and therefore improves yield after cutting for gemstones.

Furthermore, HPHT annealing, which is done typically in excess of 10,000 atm, may leave a signature in the diamond structure. The inventors discovered that the annealing processes described herein reduces or prevents the signature in the diamond structure associated with HPHT annealing. The signature in the diamond structure may be detected by diamond graders, and thus, may impact the perceived value of the diamonds, resulting in a lower selling price for the diamond.

It should also be understood that pressure in the chamber may be partly determined by reactivity of the gases 32 in the chamber 12 with the diamond 14. Furthermore, the gas 32 can be a thermally transportive material that may assist the diamonds 14 in reaching temperature equilibrium across the diamonds 14. However, in various embodiments, at a low pressure 1 Torr, the molecules may not be close enough together to function as a thermally transportive material. Various embodiments may monitor the pressure throughout the process 100 and make adjustments to maintain a desired pressure.

The process then proceeds to step 108, which heats the chamber 12. Specifically, some embodiments heat the chamber 12 such that the temperature of the diamond 14 reaches between about 1,350° C. and about 2,200° C. In general, illustrative embodiments provide an inverse relationship between the annealing time and the temperature of the annealing chamber 12. For example, the diamond 14 may achieve a temperature of about 2,200° C. for less than a minute. As another example, the diamond 14 may achieve a temperature of about 1,350° C. for several hours. The temperature of the diamond may be measured using a pyrometer and/or thermocouple.

The heat in the chamber 12 is preferably provided by the radiative heating element 16. Radiative heating provides more uniform heating throughout the diamond 14 as compared to plasma (e.g., radiative heating provides a substantially thermally uniform hot zone 22). Furthermore, as described previously, the heating element 16 is preferably radiatively heating the diamond 14 instead of conductively heating the diamond 14. The chamber 12 is configured so that the heating element 16 surrounds the diamonds 14 but does not contact the diamonds 14. Accordingly, various embodiments do not use a direct current furnace, which may disadvantageously damage the diamond 14.

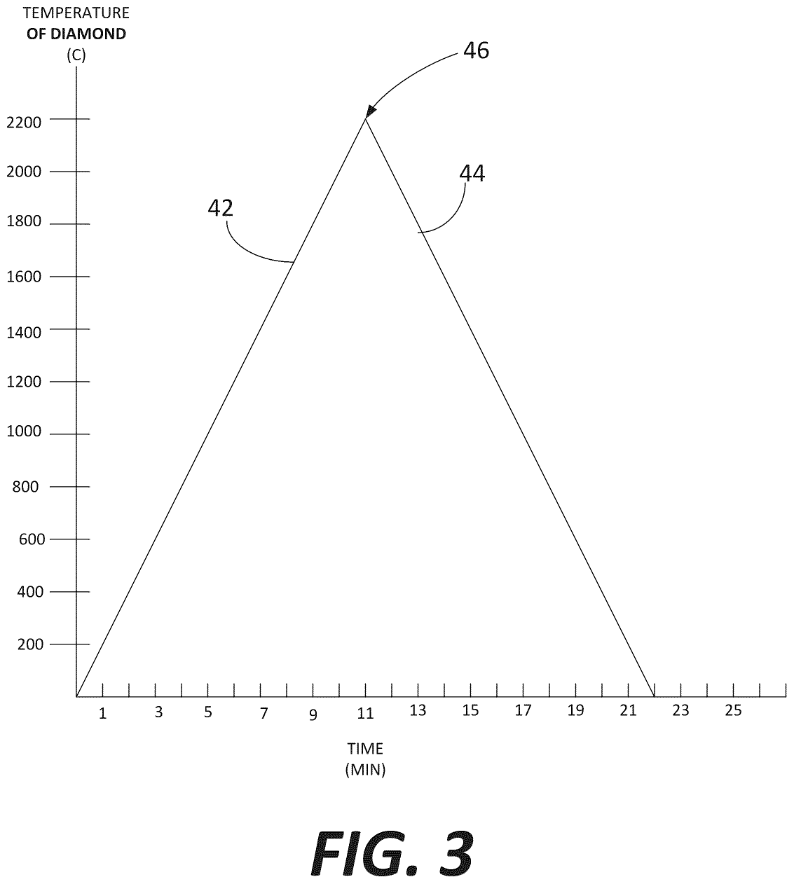

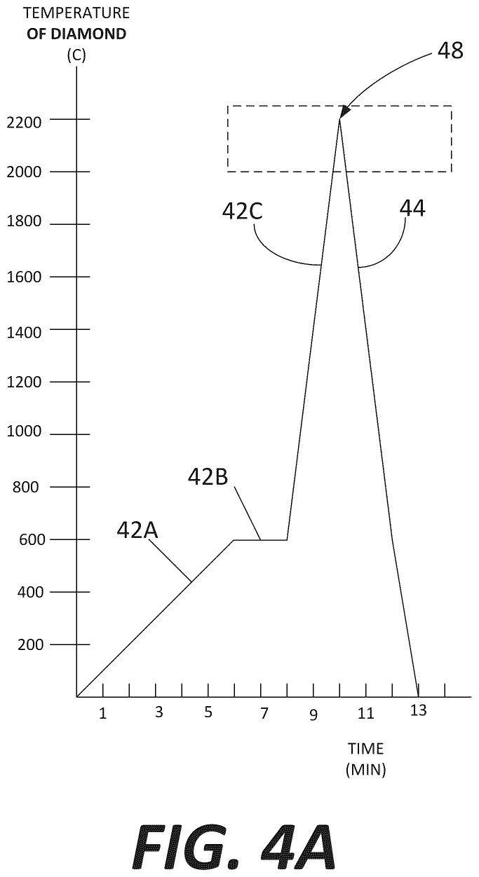

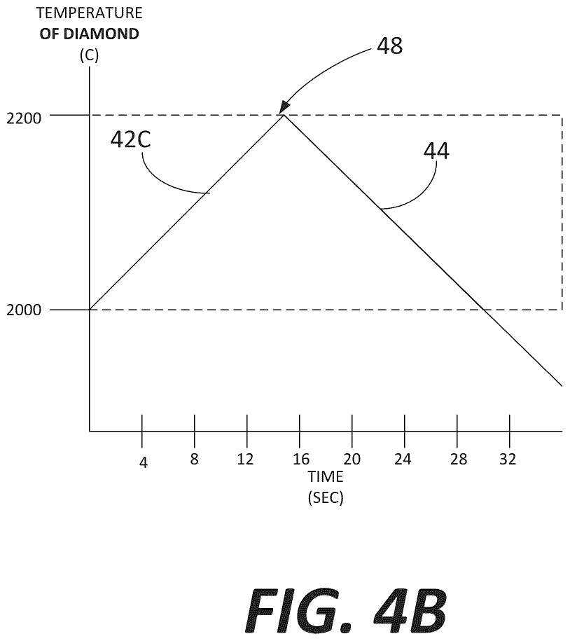

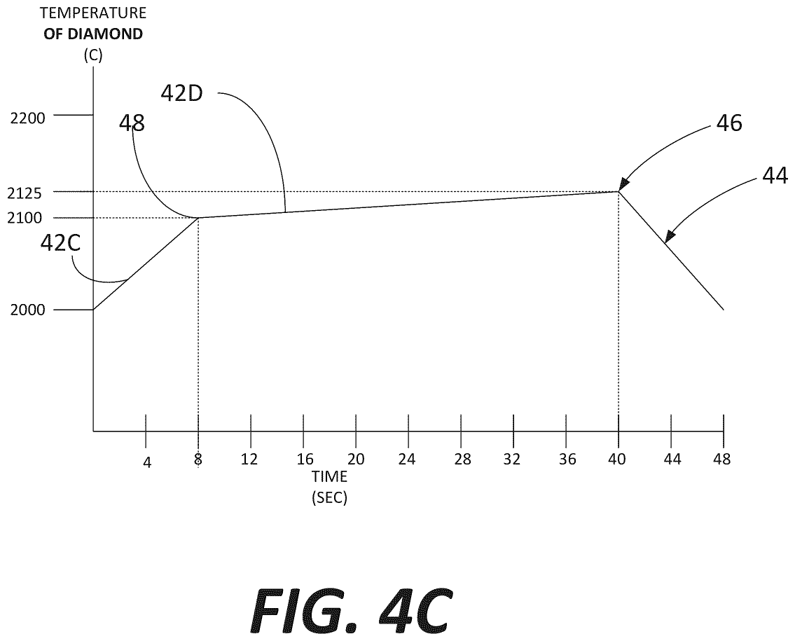

In various embodiments, the furnace 10 has a heating ramp rate 42 of between about 60 degrees C. per minute and about 800 degrees C. per minute. Preferably, the ramp rate 42 is greater than or equal to 200 degrees C. per minute. In various embodiments, a cooling ramp rate 44 has substantially the same magnitude as the heating ramp rate (but negatively sloping). The inventors have determined that greater heating ramp rate 42 and cooling ramp rate 44 help reduce graphitization. FIGS. 3 and 4A schematically show exemplary heating ramp rates 42 in accordance with illustrative embodiments of the invention. FIG. 4B schematically shows a close-up of a portion of FIG. 4A.

One skilled in the art should understand that although the heating ramp rate 42 and the cooling ramp rate 44 are represented in the figures by the temperature lines, that the ramp rate is a temperature increase per unit time. Thus, the ramp rates 42 and 44 are not the associated temperature, but instead, are the rate of increase of the temperature.

As shown in FIG. 3, the upward ramp rate 42 and the downward ramp rate 44 may be the same rate but in opposite directions. FIG. 3 schematically shows a 200 degree C. per minute heating ramp rate 42 and cooling ramp rate 44. Although the heating ramp rate 42 and the cooling ramp rate 44 are shown as identical, it should be understood that various embodiments may have different heating ramp rates 42 and cooling ramp rates 44. In various embodiments, the pressure in the chamber 12 may be in accordance with the ranges described above. For example, the chamber 12 may have a pressure of 550 Torr. Furthermore, the gas environment in the chamber 12 may be inert. In the example of FIG. 3, a constant ramp rate 42 is held until a peak temperature 46 is achieved. Then, the temperature of the diamond 14 is cooled at the cooling ramp rate 44 (which may be the same as the heating ramp rate 42).

FIG. 4A schematically shows another embodiment of the ramp rate 42 in accordance with illustrative embodiments. For the sake of discussion, the chamber 12 may be at vacuum and include a reactive gas environment. In FIG. 4A, the ramp rate 42 can be said to have three distinct segments 42A, 42B, and 42C. The ramp rate 42A is 200 degrees C./minute, the ramp rate 42B is 0 degrees C./minute (i.e., temperature is steady), and the ramp rate 42C is 800 degrees C./minute. In various embodiments, the significant parameter of the ramp rate 42 is the ramp rate 42C used to achieve a prescribed temperature 48 (e.g., greater than about 1,350° C. and less than about 2,200° C.). Thus, in various embodiments, the ramp rate 42 can be said to be the ramp rate 42C that is used to achieve the prescribed temperature 48, which may also be the peak temperature 46. Illustrative embodiments increase the ramp rate 42C to between about 60° C. /minute and about 800° C. /minute as the temperature of the diamond 14 approaches a prescribed temperature somewhere between 1,350° C. and 2,200° C. Accordingly, when referring to the ramp rate 42, various embodiments refer to the ramp rate 42C used to achieve the prescribed temperature. Thus, in various embodiments, the ramp rate 42A, 42B may be slower at the beginning of the heat process 100, but the ramp rate 42C increases as the temperature nears the prescribed temperature 48 (e.g., 2,200° C. in FIG. 4A).

FIG. 4B schematically shows a close up of the end of the ramp rate 42C of FIG. 4A. As shown in FIG. 4B, the ramp rate 42C remains high until the prescribed temperature 48 is achieved. In some embodiments, the cooling ramp rate 44 begins after the prescribed temperature 48 is achieved. The cooling ramp rate 44 may be substantially identical in magnitude to the heating ramp rate 42. However, as shown in FIG. 4C, various embodiments may have a reduced ramp rate 42 and/or a plateau after the prescribed temperature 48 is achieved.

FIG. 4C schematically shows an alternative ramp rate 42C to the ramp rate 42C shown in FIG. 4B. The conditions inside the chamber 12 may be identical to those described in FIGS. 3 and/or 4A-4B with the exception of the ramp rate 42. As shown, the ramp rate 42C is approximately 750 C/minute as the heat process reaches the prescribed temperature 48. However, after the prescribed temperature 48 is reached, the ramp rate 42D may reduce substantially (e.g., to about 47 C/minute) until a maximum temperature 46 is reached. Thus, various embodiments use a critical ramp rate (e.g., greater than about 60° C. per minute and less than about 800° C. per minute) to reach the prescribed temperature 48, and then may use a slower ramp rate 42D (or plateau the temperature). Preferably, a slower ramp rate 42D and/or the plateau does not last longer than 1 minute (in this example, the slow ramp rate 42D lasts thirty-two seconds). Furthermore, in various embodiments, the maximum temperature 46 is preferably less than 2,200 C.

It should also be noted that in various embodiments the cooling ramp rate 44 preferably is between about −60° C. per minute and about −800° C. per minute. Advantageously, this helps to cool the diamond 14 and prevents undesirable changes in the diamond that may occur if the diamond 14 is kept at high temperatures for too long.

In illustrative embodiments, an undesirable coloration in the diamond 14 is reduced or removed during the annealing process. In some embodiments, the undesirable color may be altered, rather than reduced. Although illustrative embodiments refer to an “undesirable” color, it should be understood that in some embodiments, any color that is not colorless may be undesirable. Thus, various embodiments may remove, reduce, alter or add coloration of the diamond 14. Thus, the term “undesirable” is used to describe a color that the user wishes to remove, reduce, and/or alter, and is not intended to limit illustrative embodiments to particular colors. However, in some embodiments, the “undesirable” color may include brown, yellow, pink, red, purple and/or blue. Additionally, removing or reducing the undesirable color may, for example, move the diamond up on the color scale provided by the Gemological Institute of America (e.g., from Z (light yellow or brown) towards D (colorless)). As an additional advantage, illustrative embodiments may not leave a signature in the diamond, or may leave a reduced signature in the diamond relative to HPHT annealing. Additionally, the process may produce a diamond with reduced pitting of the surface of the material relative to LPHT annealing.

After the diamond 14 is heated for a selected amount of annealing time, at an annealing pressure and an annealing temperature as described above, the next step 110 removes the diamond 14 from the chamber 12 and polishes the diamond 14. In preferred embodiments, the diamond 14 reaches the prescribed temperature 48 and/or the peak temperature 46 for a short period of time (e.g., less than a second, a single point), such that there is no plateau at the prescribed temperature 48 (which may also be the maximum temperature 46). In some embodiments, however, the diamond 14 may maintain the prescribed temperature 48 for up to 30 seconds, preferably less than seconds. The inventors discovered that prolonged periods of high temperature (e.g., a long peak plateau) causes graphitization of the diamond 14. After graphitization begins, it nucleates and expands quickly. Thus, preferred embodiments use a rapid heating ramp rate 42 and cooling ramp rate 44 and do not remain at the plateau temperature for long (e.g., reach prescribed temperature 48 only for an instant, for less than 1 second, etc.). Furthermore, in various embodiments the prescribed temperature 48 and the maximum temperature 46 are the same or substantially the same.

The process of illustrative embodiments contrasts with plasma methods, which actively etch graphite away as it is formed. Instead, illustrative embodiments use a non-plasma method, which has the added benefit of scalability because of the uniform hot zone 22. Various embodiments utilize a reducing environment in the chamber 12 to react with the oxygen and reduce graphitization rate (e.g., by injecting hydrogen). Illustrative embodiments also use fast heating ramp rates 42 to reduce the amount of time that the diamond 14 remains at high temperature, and therefore reduce the amount of graphitization that occurs. It should be apparent that while various embodiments reduce graphitization, some graphitization may still occur.

The process then moves to step 112, which asks if there are more diamonds 14 to anneal. If there are, the process returns to step 102, which positions the diamond 14, and the entire process is repeated. If there are no more diamonds 14 to reduce/remove the color from, then the process 100 comes to an end.

Disclosed embodiments, or portions thereof, may be combined in ways not listed above and/or not explicitly claimed. In addition, embodiments disclosed herein may be suitably practiced, absent any element that is not specifically disclosed herein. Accordingly, the invention should not be viewed as being limited to the disclosed embodiments.

It should be apparent that various embodiments provide a number of advantages. First, plasma is difficult to control, and the furnace 10 heating process described herein provides scalability. Furthermore, it is believed in the art that using a furnace 10 to anneal the diamond 14 causes graphitization of the material. Thus, the prior art solved this problem using hyper-reactive plasma mediated processes, or a very high pressure process where the thermodynamics favor diamond instead of graphitization. Various embodiments advantageously reduce graphitization by controlling the chamber 12 environment (gas chemistry, pressure, temperature, and ramp rate) to suppress graphitization.

As stated previously, plasma provides non-uniform heating. Thus, achieving isothermal process is not possible with plasma over a small or large hot zone 22. Plasma-mediated processes inherently have a thermal gradient. By using radiative heating, illustrative embodiments achieve substantially uniform temperature hot zones 22 (e.g., greater than 1,350° C. and within 3% of a maximum temperature within the hot zone). Accordingly, many stones 14 may be positioned in the furnace during the same heat treatment process, and each stone 14 receives substantially uniform thermal conditions.

Illustrative embodiments also provide advantages over low-pressure high-temperature annealing (e.g., e-beam or plasma heating), which require careful control of temperature and atmosphere to avoid thermal issues. Furthermore, LPHT annealing may cause cracking, or surface etching or graphitization, shrinking the viable stone size or increasing the size of inclusions. These low-pressure high-temperature annealing methods are also limited in batch size, constraining the rate of production.

Illustrative embodiments also provide advantages over high-pressure high-temperature annealing, which can provide the desired annealing but introduces considerable equipment expense. That process tends to impart its own defects such as color tint from the pressure medium or undesirable inclusions.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Although the above discussion discloses various exemplary embodiments of the invention, it should be apparent that those skilled in the art can make various modifications that will achieve some of the advantages of the invention without departing from the true scope of the invention.

What is claimed is:

1. A method of annealing one or more diamonds, the method comprising:
providing a furnace having a chamber, the furnace having a heating element configured to radiatively heat a diamond;
positioning the diamond within the chamber;
modulating levels of a gas within the chamber to achieve a prescribed pressure; and
heating the diamond to a prescribed temperature using a given heating ramp rate;
the given ramp rate being greater than about 60° C. per minute and less than about 800° C. per minute,
the prescribed temperature being greater than about 1,350° C. and less than about 2,200° C., and
the prescribed pressure being greater than 1×10\hat{ }−9 Torr and less than about 550 Torr.

2. The method as defined by claim 1, wherein graphitization of the diamond is prevented.

3. The method as defined by claim 1, wherein the ramp rate accelerates as it approaches the prescribed temperature.

4. The method as defined by claim 1, wherein the prescribed temperature is a maximum temperature, and the maximum temperature is sustained for a time that is more than an order of magnitude less than a ramp time.

5. The method as defined by claim 1, wherein the prescribed temperature is maintained for less than 2 seconds.

6. The method as defined by claim 1, wherein the prescribed temperature is maintained for less than 30 seconds.

7. The method as defined by claim 1, wherein the ramp rate is between about 150° C. per minute and less than about 500° C. per minute.

8. The method as defined by claim 1, wherein the prescribed temperature is between about 1,750° C. and about 2,100° C.

9. The method as defined by claim 1, further comprising positioning a plurality of diamonds within the chamber; and
simultaneously heating the plurality of diamonds using the given ramp rate to achieve substantial thermal uniformity for each of the diamonds at the prescribed temperature.

10. The method as defined by claim 9, wherein the plurality of diamonds includes at least 50 diamonds.

11. The method as defined by claim 1, wherein the prescribed gas environment includes hydrogen.

12. The method as defined by claim 1, wherein the prescribed gas environment includes argon and/or nitrogen.

13. The method as defined by claim 1, wherein the gas environment is less than 1 ppm.

14. The method as defined by claim 1, wherein the partial pressure of oxygen in the chamber is less than 10 milliTorr.

15. The method as defined by claim 1, wherein a plurality of diamonds are maintained at substantially the same temperature.

16. A method of annealing a plurality of diamonds, the method comprising:
providing a furnace having a chamber, the furnace having a radiative heating element configured to radiatively heat a diamond;
positioning the plurality of diamonds within the chamber;
modulating levels of a gas within the chamber to achieve a prescribed pressure;
producing a hot zone within the chamber using the radiative heating element, the hot zone reaching a prescribed temperature using a given heating ramp rate, the hot zone defining a volume configured to encompass the plurality of the diamonds, the hot zone having a thermal variance of less than 3% of a maximum temperature of the hot zone;
the given ramp rate being between about 60° C. per minute and about 800° C. per minute,
the prescribed temperature being between about 1,350° C. and about 2,200° C.;
the prescribed pressure being between 1×10\hat{ }−9 Torr and about 550 Torr.

17. The method as defined by claim 16, further comprising heating the diamonds in the hot zone.

18. The method as defined by claim 16, wherein the plurality of diamonds are grown in the chamber.

19. The method as defined by claim 16, wherein the prescribed temperature and/or the prescribed pressure varies during the process.

20. The method as defined by claim 16, wherein the uniform hot zone has a width of between about 3 inches and about 5 inches, and a height of between about 3 inches and about 7 inches.

21. A method of reducing undesirable coloration in a diamond, the method comprising:
providing a diamond having a discoloration; and
annealing the diamond in a furnace having a chamber at a pressure of between about 40 Torr and about 550 Torr, wherein the diamond is radiatively heated to a maximum temperature of between about 1,350° C. and about 2,200° C., so as to reduce the discoloration.

22. The method as defined by claim 21, further comprising:
positioning the diamond having the discoloration in an annealing chamber.

23. The method as defined by claim 21, wherein the annealing takes place in the diamond growth chamber.

24. The method as defined by claim 21, wherein the maximum temperature is achieved for less than a second.

25. The method as defined by claim 21, wherein a heating ramp rate is between about 150° C. and about 800° C.

26. The method as defined by claim 21, wherein the annealing occurs in the presence of hydrogen and/or an inert gas.

27. A furnace for heating the diamonds, the furnace comprising:
a hermetically sealed chamber;
a growth stage in the hermetically sealed chamber, the growth stage configured to hold a plurality of diamonds;
a radiative heating element, the radiative heating element configured to radiatively heat the plurality of diamonds to prescribed temperatures of between about 1,350° C. and less than about 2,200° C., the radiative heating element further configured to having a heating ramp rate of about 60° C. per minute and less than about 800° C. per minute when heating in, or to, the prescribed temperature range;
a pressure modulation system configured to adjust a pressure within the chamber, the pressure modulation system configured to adjust the pressure within the chamber from between about 1×10\hat{ }−9 Torr and less than about 550 Torr.

28. The furnace as defined by claim 27, further comprising a gas input and a gas output.

29. The method as defined by claim 1, wherein the annealing process results in less than 1% loss of diamond by weight due to graphitization.
